(19) United States
(12) Patent Application Publication
(10) Pub. No.: US 2008/0054431 A1
(43) Pub. Date: Mar. 6, 2008

(54) Embedded package in package

(76) Inventors: Tingqing Wang, Shanghai (CN); Moon Wang, Shanghai (CN); Bin Yu, Shanghai (CN)

Correspondence Address: TROP PRUNER & HU, PC, 1616 S. VOSS ROAD, SUITE 750, HOUSTON, TX, 77057-2631, US

(21) Appl. No.: 11/513,765

(22) Filed: Aug. 31, 2006

(51) Int. Cl. H01L 23/12; H01L 21/58

(52) U.S. Cl. 257/686; 257/723; 438/109; 438/125

(57) ABSTRACT

A stacked chip semiconductor package may be formed in a “package in package” arrangement. The internal package may include two substrates. One substrate may have two dice stacked on each of two opposed sides and the other substrate may have two dice stacked on it as well. The two stacked substrates may be separated by molding compound and then electrically coupled to a third substrate. Thereafter, the entire assembly may be encapsulated.

### BACKGROUND

This relates generally to integrated circuit packages which include at least two stacked dice.

Stacked chip scale packages (SCSP) allow at least two integrated circuit dice to be mounted on the same substrate. As used herein, a substrate is any structure, other than a die, used for electrically interconnecting two dice together.

Thus, in conventional SCSP packages, there is one substrate and two stacked dice mounted on that substrate. The substrate may be connected on one side to the dice and on the other side to interconnects such as solder balls.

In package-on-package technology, two substrates may be utilized instead of one. One of those substrates may mount two stacked dice in an SCSP arrangement and the other of the substrates may mount one die, mounted between the SCSP package and the second substrate.

While these packaging options have many advantages, there is a desire to stack even more dice within ever smaller packages.

### BRIEF DESCRIPTION OF THE DRAWINGS

FIG. 1 is an enlarged, cross-sectional view of one embodiment of the present invention;

FIG. 2 is an enlarged, cross-sectional view of the embodiment shown in FIG. 1 at an early stage of manufacture in accordance with one embodiment of the present invention;

FIG. 3 is an enlarged, cross-sectional view at a subsequent stage to that shown in FIG. 2 in accordance with one embodiment of the present invention;

FIG. 4 is an enlarged, cross-sectional view at a subsequent stage in accordance with one embodiment of the present invention;

FIG. 5 is an enlarged, cross-sectional view at a subsequent stage in accordance with one embodiment of the present invention;

FIG. 6 is an enlarged, cross-sectional view at a subsequent stage in accordance with one embodiment of the present invention;

FIG. 7 is a schematic depiction of one embodiment of the present invention; and

FIGS. 8-10 are cross-sectional depictions of a mold chase in accordance with one embodiment of the present invention.

### DETAILED DESCRIPTION

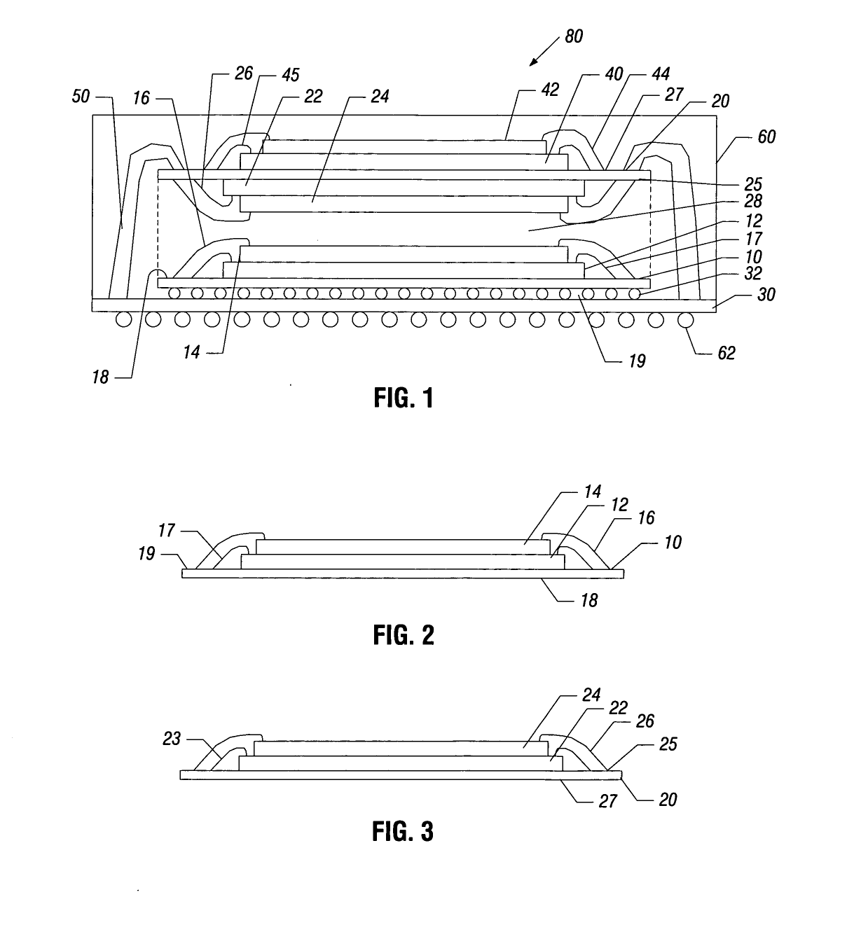

Referring to FIG. 1, in accordance with some embodiments of the present invention, a plurality of substrates mounting a plurality of dice may be contained all within the same integrated circuit package. While an embodiment is described with a ball grid array or solder ball external interconnect, other arrangements are also possible. For example, 1 and grid arrays may also be utilized.

In some embodiments of the present invention, three or more substrates may be utilized with six or more dice. Two substrates coupled to a third substrate may effectively float within an encapsulant. Each of the floating substrates may be coupled to multiple dice. The uppermost floating substrate may, in fact, be coupled to four dice, with two dice stacked on each side. Other numbers of dice, substrates, and arrangements may be used in some embodiments.

Referring to FIG. 1, the base substrate 30 may be coupled to an interconnect such as solder balls 62. The floating substrates 10 and 20 may be encapsulated within an encapsulant or molding compound 60. Any suitable substrate may be utilized, including flex substrates such as folded flex substrates or flexible polyimide tape, laminate substrates such as bismaleimide triazine (BT) substrates, buildup substrates, or ceramic substrates.

The upper floating substrate 20 may be coupled to stacked dice 40 and 42 on its upper side 27 and stacked dice 22 and 24 on its lower side 25. Die attach adhesives (not shown), such as epoxy, may be used to secure stacked dice to one another and to a substrate. The adhesive may be epoxy and may be conductive or non-conductive. Other options include paste and adhesive tape.

Thus, in some embodiments, the upper side 27 and lower side 25 of the upper floating substrate 20 may include bond fingers. The upper die 42 may be coupled by wire bonds 44 to the bond finger side 27 of the substrate 20 and the lower die 40 may be coupled by wire bonds 45 to the bond finger side 27 of the substrate 20. The lowermost die 24 may be coupled by a wire bonds 26 to the bond finger side 25 of the substrate 20. The die 22 is coupled to the substrate 20 by wire bonds 23.

An encapsulant 28 separates the assembly coupled to the upper floating substrate 20 from the assembly including the lower floating substrate 10. In some embodiments, a spacer is unnecessary between the substrate 10 and substrate 20.

The lower floating substrate 10 may include solder balls, conductive adhesive film, or other interconnects 32 which couple to the base substrate 30. On the upper side 18, the lower floating substrate 10 may have stacked dice 12 and 14. The upper die 14 may be coupled by wire bonds 16 to the substrate 10. The lower die 12 may be coupled by wire bonds 17 to the substrate 10. The substrate 30 may be coupled to the upper floating substrate 20 by wire bonds 50.

The stacked dice, such as dice 40 and 42, 22 and 24, and 12 and 14, electrically communicate directly between themselves using conventional technology. Communications from substrates to the farthest spaced die of each stack may be enabled by wire bonds in one embodiment of the present invention. In some embodiments, the wire bonds may be gold wire bonds but other metals may also be used.

Any of a variety of SCSP, including ultra-thin SCSP (UT-SCSP), may be utilized for the individual sets of substrate and stacked dice coupled thereto. Any conventional molding material may be utilized for the encapsulant 28 or 60. In some embodiments, the encapsulant 28 and 60 may be the same material and, in some embodiments, they may be different materials.

In the case of the substrate 10, the two sides 18, 19 of the substrate may be differently configured. The side 18 may be configured for attachment of solder balls, conductive adhesive film, or other connection material, in one embodiment, and may include solder ball pads, while the other side 19 may be configured with bond finger pads.

In some embodiments of the present invention, the configuration shown in FIG. 1 may result in a package having an overall thickness which is less than is possible with other packaging technologies, packaging the same number of dice.

Referring to FIGS. 2-6, one embodiment of the assembly of the structure shown in FIG. 1 is illustrated. In FIG. 2, the lower floating substrate 10 is made up with the stacked dice 12 and 14 and the wire bonds 16. The side 18 may be configured for solder ball pads or conductive adhesive film pads, as examples, and the side 19 may be configured for bond fingers. Bond wires 16 may be utilized to interconnect the substrate 10 to the upper die 14 which then, in turn, connects at the common interface electrically and mechanically to the die 12. In one embodiment, the dice 12 and 14 are adhesively coupled and adhesively coupled to the substrate 10.

Referring next to FIG. 3, one assembly of the SCSP stack, including the substrate 20 and the stacked dice 22 and 24, is illustrated. Again, wire bonds 23, 26 may be utilized from the side 25 having bond fingers. The side 27 may also be configured for bond fingers in some embodiments. Again, the dice and substrate may be adhesively connected in one embodiment.

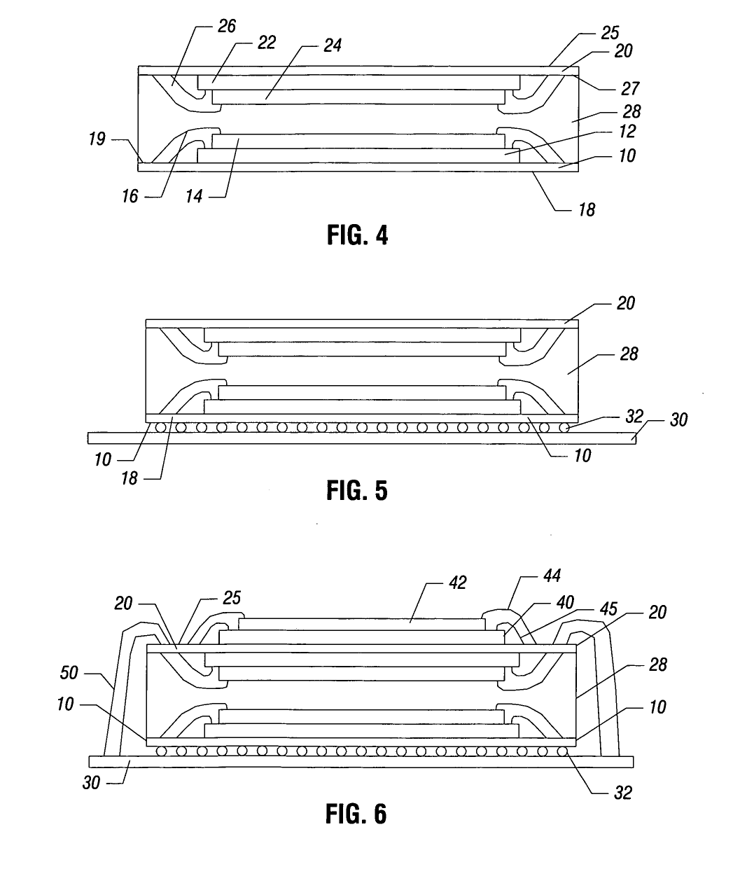

Then, referring to FIG. 4, the substrate 20 may be inverted and positioned over the substrate 10. The substrates 10 and 20 are molded together with a molding compound or encapsulant 28. Thus, in some embodiments, no spacer is needed between the substrates 10 and 20, the spacing function being formed by the encapsulant or molding compound 28. In this arrangement, the substrates 10 and 20 are spaced apart by intervening encapsulant 28.

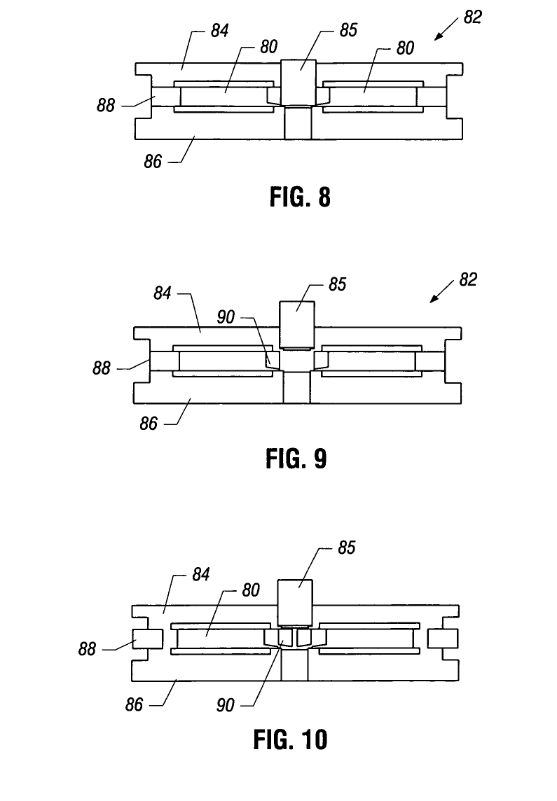

A mold chase 82 may be configured with a bottom chase 86 and a top chase 84 as shown in FIG. 8. Both the bottom and top chases may be designed with a vacuum chuck function. The substrate 10 is transferred from an onload to the bottom chase 86 and chucked by the bottom chase 86 with vacuum. The substrate 20 is picked up from an onload and inverted by an inverter arm and then transferred to the top mold chase 84 and chucked by a vacuum and clamped. Finally, the bottom chase 86, middle-plate 88, and top chase 84 are clamped and an encapsulant is injected by a plunger 85 between the chases as shown in FIG. 8. The plunger 85 is raised as shown in FIG. 9. Then, the middle plate elements 90 are pulled together as shown in FIG. 10. Finally, the top chase 84 is pulled away leaving the packages 80 on the bottom chase 86.

Then, referring to FIG. 5, the molded assembly including the substrates 10 and 20, coupled by encapsulant 28, may be coupled to the base substrate 30, for example, through solder balls or other interconnects 32. Thus, the side 18 of the lower floating substrate 10, adapted with solder ball pads, may be coupled by solder balls 32 to the base substrate 30. In another embodiment (not shown), one or more dice may be secured to the side 19, together with interconnects 62.

As shown in FIG. 6, the resulting assembly may be wire bonded using wire bonds 50 from substrate 20 to substrate 30. Then, two additional stacked dice 40 and 42 may be mounted on a bond pad side 27 of the substrate 20. The dice 40 and 42 may be coupled to each other and the substrate 20 by adhesive, as one example. Wire bonds 44 may couple the die 42 to the substrate 20. Wire bonds 45 may couple the die 40 to the substrate 20. Thereafter, the structure of FIG. 6 is encapsulated and the balls 62 attached, resulting in the package shown in FIG. 1.

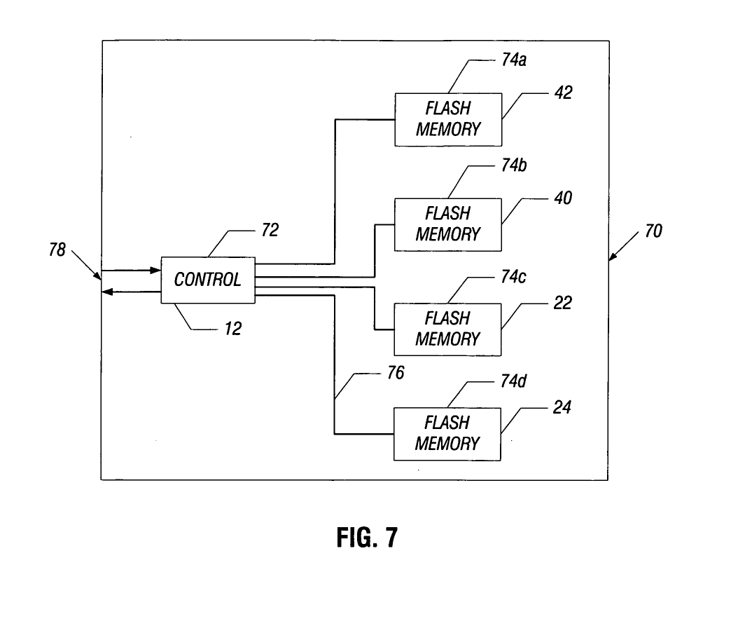

Referring to FIG. 7, in accordance with one embodiment of the present invention, a universal serial bus (USB) flash memory 70 may be formed in one package, as described herein. In this example, only five dice are stacked, the die 14 being omitted. The memory 70 includes a control 72 which may be implemented as the die 12 on the substrate 10. Then, four flash memories 74a, 74b, 74c, and 74d may be coupled to the control 72. The flash memory 74a may be implemented by the die 42, the flash memory 74b may be implemented by the die 40, the flash memory 74c may be implemented by the die 22, and the flash memory 74d may be implemented by the die 24.

Interconnects 76 couple the control 72 to the flash memories 74a-74d. The interconnects 76 may be made up of the substrates 10, 20, and 30, as well as the wire bonds 44, 26, 50, and 16 and solder balls 32 and 62. The entire assembly may then be coupled to the outside world via the base substrate 30 and solder balls 62 in one embodiment. In some cases, it may be desirable to attach high frequency signals to the dice 12 and 14, due to their short wire and circuit connection to the external input/output. For lower frequency signals, the other dice may be utilized. For the same device, it may be desirable to use the same level wire or circuit length in order to make the signals synchronous.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
molding together a pair of spaced substrates, each including at least two stacked dice; and
forming a package including said substrates electrically coupled to a third substrate.

2. The method of claim 1 wherein molding together a pair of spaced substrates includes molding together a pair of substrates, each substrate including a die mounted on the substrate.

3. The method of claim 2 wherein molding together a pair of spaced substrates includes molding the substrates together with their dice facing one another.

4. The method of claim 3 including molding said substrates together without using an intervening spacer.

5. The method of claim 3 including forming an encapsulant between said spaced substrates.

6. The method of claim 1 including coupling said molded spaced substrates to said third substrate using solder balls.

7. The method of claim 1 including wire bonding said substrates to said dice.

8. The method of claim 1 including securing a die to one of said spaced substrates after molding said spaced substrates together.

9. The method of claim 8 including mounting a pair of stacked dice on one of said substrates after molding said two substrates together.

10. The method of claim 9 including wire bonding from said third substrate to said substrate to which said stacked dice are mounted after molding together said spaced substrates.

11. A semiconductor integrated circuit package comprising:
a first and second substrate, each substrate including at least one integrated circuit die mounted thereon;
encapsulant securing said first and second substrates together; and
a third substrate electrically coupled to said first and second substrates.

12. The package of claim 11 wherein said first and second substrate each include at least two dice mounted thereon.

13. The package of claim 12 wherein at least one of said first and second substrates includes at least three dice mounted thereon.

14. The package of claim 13 wherein at least one of said first and second substrates includes at least four dice mounted thereon.

15. The package of claim 11 wherein one of said first and second substrates is coupled to said third substrate by solder balls.

16. The package of claim 15 wherein the other of said first and second substrates is coupled to said third substrate by wire bonds.

17. The package of claim 11 including at least six dice.

18. The package of claim 11 wherein one of said first and second substrates includes bond pads on both sides.

19. The package of claim 18 wherein the other of said first and second substrates includes bond pads on one side and solder ball pads on the opposite side.

20. The package of claim 11 wherein only encapsulant separates said first and second substrates.

21. A packaged memory comprising:
a package;
at least four memory devices in said package;
a control, with said package, coupled to said devices; and
at least three substrates in said package, said control being a die on a first substrate, and said first and second substrates mounting dice to act as said memory devices, said first and second substrates being separated only by encapsulant.

22. The memory of claim 21 including an encapsulant between said second and third substrates.

23. The memory of claim 21 wherein some of said devices are mounted on said second substrate and the others of said devices are mounted on the third substrate.

24. The memory of claim 21 wherein said third substrate is wire bonded to said first substrate.

25. The memory of claim 21 wherein said first substrate is directly mounted on said third substrate.

26. The memory of claim 25 wherein said first substrate is coupled by solder balls to said third substrate.

27. The memory of claim 26 wherein said third substrate includes external interconnects on the package.

28. The memory of claim 27 wherein said die for said control is the die closest to said external interconnects.
